(19) United States
(12) Patent Application Publication
(10) Pub. No.: US 2026/0158646 A1
(43) Pub. Date: Jun. 11, 2026

(54) SUBSTRATE TRANSFER APPARATUS, SUBSTRATE TRANSFER METHOD, AND COMPUTER-READABLE STORAGE MEDIUM

(71) Applicant: Tokyo Electron Limited, Tokyo (JP)

(72) Inventors: Seita TAMAI, Albany, NY (US); Tomohiro NODA, Koshi City (JP)

(21) Appl. No.: 19/411,947

(22) Filed: Dec. 8, 2025

(30) Foreign Application Priority Data
Dec. 10, 2024 (JP) 2024-215913

(51) Int. Cl. B25J 9/16; B25J 11/00; H10P 72/50; H10P 72/76

(52) U.S. Cl. CPC B25J 9/1628; B25J 11/0095; H10P 72/50; H10P 72/7602

(57) ABSTRACT

A substrate transfer apparatus for transferring a substrate to a rotary processor, which is provided in a common housing with a thermal processor for performing thermal processing on the substrate and configured to hold and rotate the substrate for processing, includes: a transfer arm that supports and moves the substrate; and a controller that controls an operation of the transfer arm, wherein the controller performs: when a setting of a processing temperature in the thermal processor is changed, acquiring a correction amount of a delivery position, which is a position of the transfer arm when the substrate is delivered to the rotary processor; determining a correction direction of the delivery position according to an elapsed time after the setting is changed; and adjusting the delivery position based on the acquired correction amount and the determined correction direction.

### CROSS-REFERENCE TO RELATED APPLICATION

This application is based upon and claims the benefit of priority from Japanese Patent Application No. 2024-215913, filed on Dec. 10, 2024, the entire contents of which are incorporated herein by reference.

### TECHNICAL FIELD

The present disclosure relates to a substrate transfer apparatus, a substrate transfer method, and a non-transitory computer-readable storage medium.

### BACKGROUND

Patent Document 1 discloses a technique for stopping a transfer mechanism at a target position.

### PRIOR ART DOCUMENTS

### Patent Documents

[Patent Document 1] Japanese Patent Application Publication No. 2013-230036

### SUMMARY

According to one embodiment of the present disclosure, there is provided a ...

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view showing a schematic configuration of a coating-and-developing apparatus as a substrate processing system including a substrate transfer apparatus according to an embodiment.

FIG. 2 is a view showing a schematic configuration of a central portion of the coating-and-developing apparatus in a depth direction (X direction).

FIG. 3 is a view showing a schematic configuration of a first stacking block.

FIG. 4 is a view showing a schematic configuration of a resist film forming module.

FIG. 5 is a view showing a schematic configuration of a heating module.

FIG. 6 is a side view showing a schematic configuration of a main transfer mechanism.

FIG. 7 is a diagram showing changes in a wafer shift direction according to an elapsed time after a setting of a processing temperature in the heating module is changed.

FIG. 8 is a diagram showing correspondence of a wafer shift amount to an amount of change in an atmospheric temperature in the heating module during a predetermined period of time.

FIG. 9 is a functional block diagram of a controller, and is a functional block relating to transfer of a wafer to the resist film forming module.

FIG. 10 is a flowchart illustrating an example of a flow of adjusting a delivery position.

FIG. 11 is a plan view showing a schematic configuration of a modification of the coating-and-developing apparatus including the substrate transfer apparatus according to the embodiment.

FIG. 12 is a view showing a schematic internal configuration of a front side of the coating-and-developing apparatus of FIG. 11.

FIG. 13 is a view showing a schematic internal configuration of a rear side of the coating-and-developing apparatus of FIG. 12.

FIG. 14 is a longitudinal cross-sectional side view showing a schematic internal configuration of the coating-and-developing apparatus of FIG. 13.

FIG. 15 is a side view of a transfer mechanism.

### DETAILED DESCRIPTION

Hereinafter, a substrate transfer apparatus and a substrate transfer method according to the present embodiment will be described below with reference to the drawings. Throughout the present disclosure and the drawings, elements having substantially the same functional configuration are denoted by the same reference numerals, and redundant description thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Coating-and-Developing Apparatus

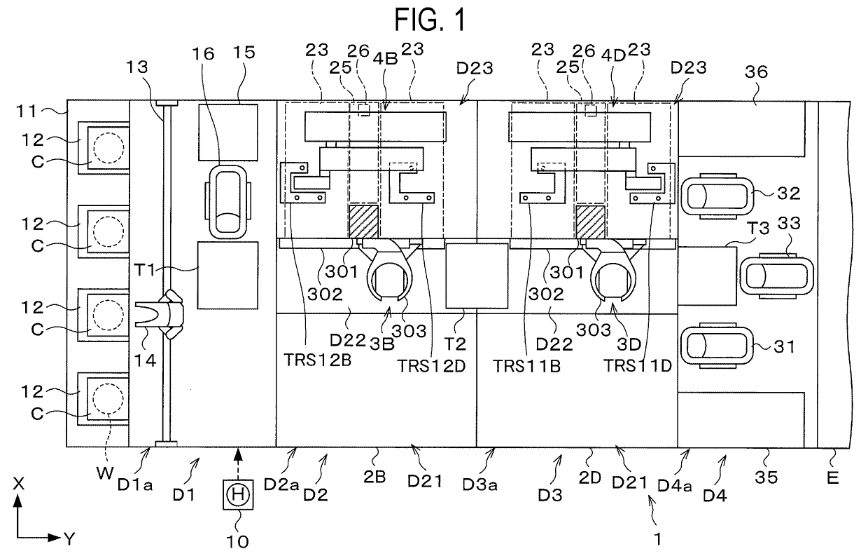

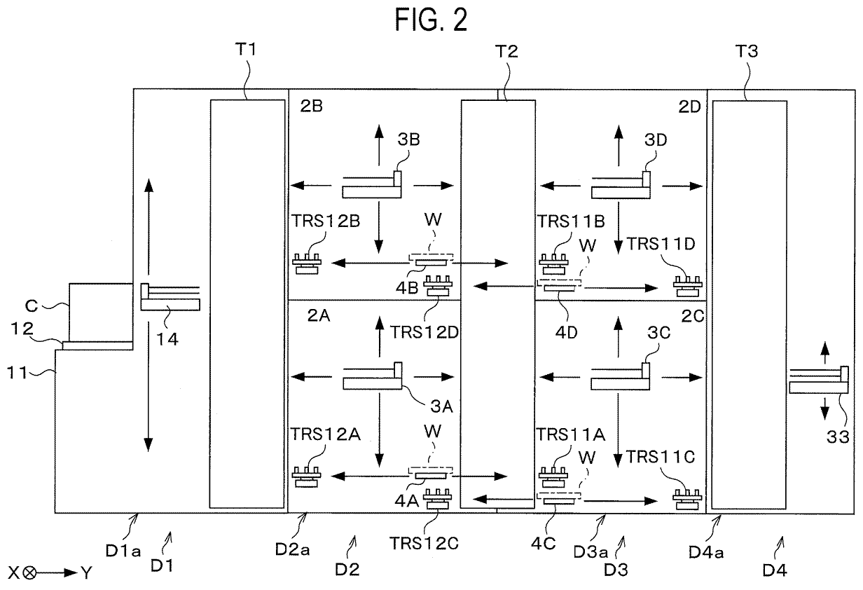

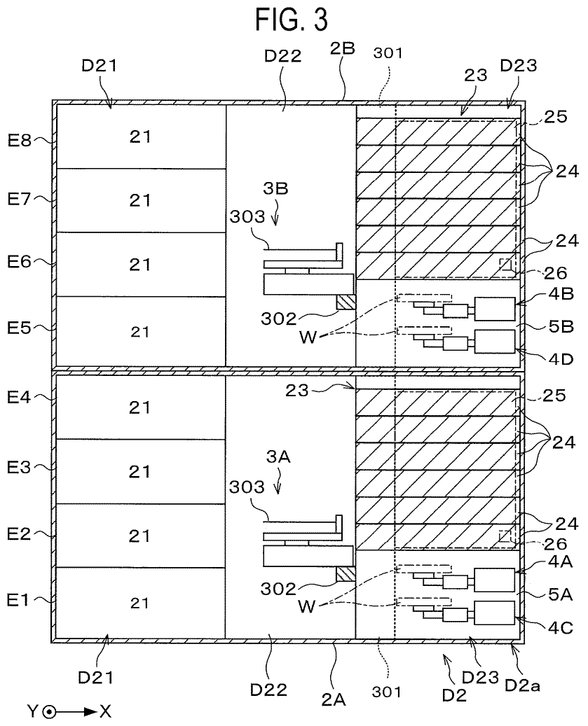

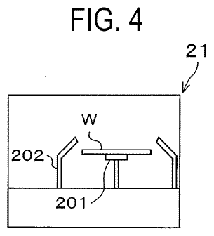

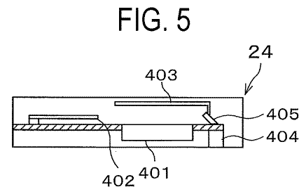

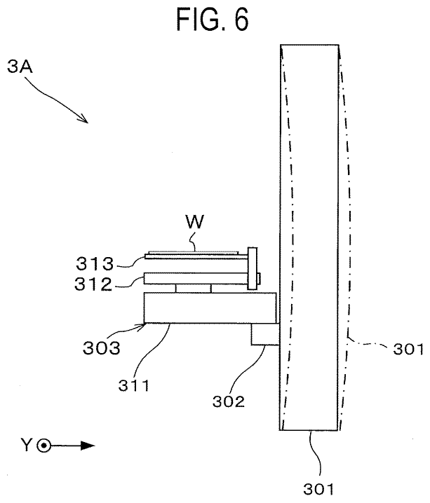

FIG. 1 is a plan view showing a schematic configuration of a coating-and-developing apparatus 1 as a substrate processing system including a substrate transfer apparatus according to the present embodiment. FIG. 2 is a view showing a schematic configuration of a central portion of the coating-and-developing apparatus 1 in a depth direction (X direction). FIG. 3 is a view showing a schematic configuration of a first stacking block D2 to be described later. FIG. 4 is a view showing a schematic configuration of a resist film forming module 21 to be described later. FIG. 5 is a view showing a schematic configuration of a heating module 24 to be described later. FIG. 6 is a side view showing a schematic configuration of a main transfer mechanism 3A to be described later.

As shown in FIGS. 1 and 2, the coating-and-developing apparatus 1 includes a carrier block D1, the first stacking block D2, a second stacking block D3, and an interface block D4, which are arranged side by side in this order in a width direction (Y direction in FIG. 1 and the like). Adjacent blocks among the carrier block D1, the first stacking block D2, the second stacking block D3, and the interface block D4 are connected to each other. Further, the carrier block D1, the first stacking block D2, the second stacking block D3, and the interface block D4 include housings D1a, D2a, D3a, and D4a, respectively, and are separated from one another. Transfer regions for semiconductor wafers (hereinafter referred to as “wafers”) W as substrates are formed in the housings D1a, D2a, D3a, and D4a.

An exposure apparatus E is connected to the interface block D4 on an opposite side of the second stacking block D3 (a positive side in the Y direction).

The wafers W are transferred to the coating-and-developing apparatus 1 while being stored in a carrier C, which is called, for example, a front opening unify pod (FOUP). Each of the first stacking block D2 and the second stacking block D3 is vertically bisected. Each section forms a processing block, which has a processing module and a main transfer mechanism for transferring the wafer W to the processing module. Hereinafter, a lower section and an upper section of the vertically bisected first stacking block D2 are referred to as a processing block 2A and a processing block 2B, respectively. Similarly, a lower section and an upper section of the vertically bisected second stacking block D3 are referred to as a processing block 2C and a processing block 2D, respectively.

The processing blocks 2A and 2C are adjacent to each other in the horizontal width direction (Y direction). The processing blocks 2A and 2C may be collectively referred to as a lower processing block. Further, the processing blocks 2B and 2D are adjacent to each other in the horizontal width direction (Y direction). The processing blocks 2B and 2D may be collectively referred to as an upper processing block. FIG. 1 shows the upper processing block. In each of the processing blocks 2B and 2D constituting the upper processing block, a shuttle (also referred to as a bypass transfer mechanism) is provided. The shuttle transfers the wafer W toward a block on a downstream side of a transfer path without going through the processing module.

In addition, a “module” refers to a location, other than the transfer mechanism (including the shuttle), where the wafer W is placed. While a module that performs processing for the wafer W is referred to as a processing module as described above, the processing also includes acquiring images for inspection.

In the carrier block D1, a carrier stages 11 are provided at an end portion of the carrier block D1 on an opposite side of the first stacking block D2 (a negative side in the Y direction in FIGS. 1 and 2). In the carrier stages 11, a plurality of mounting plates 12, on which the carriers C are mounted when loaded and unloaded with respect to the coating-and-developing apparatus 1, is arranged in the depth direction (X direction in FIG. 1 and the like).

In the carrier block D1, a delivery tower T1 is provided at an end portion of the carrier block D1 on a side of the first stacking block D2 (the positive side in the Y direction in FIG. 1 and the like) and at a central portion of the carrier block D1 in the depth direction (X direction). The delivery tower T1 is configured such that modules, including delivery modules on which the wafers W are temporarily placed, are stacked in multiple stages in the vertical direction.

In the carrier block D1, a transfer mechanism 14, which is movable on a transfer path 13 extending in the depth direction (X direction), is provided at a central portion of the carrier block D1 in the horizontal width direction (Y direction). The transfer mechanism 14 is movable vertically and around a vertical axis (θ direction), and can transfer the wafer W between the carriers C on the mounting plates 12 and the modules in the delivery tower T1.

In the carrier block D1, a hydrophobilizing module 15, which performs a hydrophobilizing process on the wafer W, is provided on a rear side of the delivery tower T1 (a positive side in the X direction in FIG. 1 and the like) and at a rear end of the carrier block D1. A plurality of hydrophobilizing modules 15 may be stacked vertically in multiple stages.

In the carrier block D1, a transfer mechanism 16 is provided between the delivery tower T1 and the hydrophobilizing module 15. The transfer mechanism 16 is movable vertically and around a vertical axis (θ direction), and can transfer the wafer W between the modules in the delivery tower T1 and the hydrophobilizing module 15, between the modules in the delivery tower T1, and the like. The transfer mechanism 16 can also transfer the wafer W with respect to a delivery module TRS12B for a shuttle 4B provided in the processing block 2B.

As shown in FIG. 3, the first stacking block D2 has two stages of rotary processing regions D21 on a front side (a negative side in the X direction). In each of the rotary processing regions D21, the resist film forming module 21 as a rotary processor is provided. Specifically, a plurality of (four in the illustrated example) resist film forming modules 21 are provided. Specifically, each of the rotary processing regions D21 is divided vertically into a plurality of (four in the illustrated example) layers, and the resist film forming module 21 is provided in each layer. Hereinafter, the four layers included in a lower rotary processing region D21 are referred to as layers E1 to E4 sequentially from bottom, and the four layers included in an upper rotary processing region D21 are referred to as layers E5 to E8 sequentially from bottom. The lower rotary processing region D21 (i.e., the lower layers E1 to E4) is included in the processing block 2A, and the upper rotary processing region (i.e., the upper layers E5 to E8) is included in the processing block 2B.

As shown in FIGS. 1 and 3, a wafer (W) transfer region D22 is provided on a rear side (the positive side in the X direction) of the rotary processing region D21 (i.e., the layers E5 to E8) of the processing block 2B. The transfer region D22 extends from one end to the other end of the processing block 2B in the width direction (Y direction) to have a belt-like shape in a plan view, and is formed across the layers E5 to E8 in the vertical direction. A thermal processing region D23 is provided on a rear side (the positive side in the X direction) of the transfer region D22. That is, the rotary processing region D21 and the thermal processing region D23 face each other via the transfer region D22. In the thermal processing region D23, a processing module stack 23 in which heating modules 24 as thermal processors are stacked in multiple stages (six stages in the illustrated example). For example, two processing module stacks 23 are provided with a gap in the width direction (Y direction). The heating module 24 performs, for example, heating to remove a solvent in a resist film on the wafer W.

For example, a portion of a main transfer mechanism 3B as a substrate transfer apparatus is located in the transfer region D22. The main transfer mechanism 3B is movable in the width direction (Y direction in the drawings), in the vertical direction, and around a vertical axis (θ direction), and can transfer the wafer W to each processing module in the processing block 2B. The main transfer mechanism 3B can transfer the wafer W to modules located at the same height as the processing block 2B, among modules in the delivery tower T1 adjacent to the processing block 2B in the width direction (Y direction in the drawings) and in a delivery tower T2 to be described below. Further, the main transfer mechanism 3B can transfer the wafer W to a delivery module TRS for the shuttle 4B provided in the processing block 2B.

A partitioned and flat space 5B is provided below the processing module stack 23 in the thermal processing region D23. The space 5B is formed from one end of the processing block 2B to the other thereof in the width direction (Y direction). The shuttle 4B and shuttle delivery modules TRS12B and TRS12D are provided in the space 5B.

Further, an exhaust duct 25 connected to the heating module 24 is provided in the thermal processing region D23. The exhaust duct 25 guides a gas discharged from the heating module 24 to the outside of the coating-and-developing apparatus 1.

The exhaust duct 25 is provided at a location among the plurality of heating modules 24 in the thermal processing region D23 and at a location on a rear side (the positive side in the X direction in the drawings) of a vertical guide 301 (to be described later) of the main transfer mechanism 3B. Specifically, the exhaust duct 25 is provided at a location between the processing module stacks 23 in the thermal processing region D23 and at a location adjacent to the rear side of the vertical guide 301.

A temperature sensor 26 as a measurer is provided in the exhaust duct 25. The temperature sensor 26 measures a temperature of the exhaust duct 25 as a position relating to the thermal processing of the heating module 24. Specifically, the temperature sensor 26 is provided, for example, in a portion of the exhaust duct 25 on a downstream side in an exhaust direction, and measures an internal temperature of the exhaust duct 25. A result measured by the temperature sensor 26 is output to a controller 10 which will be described later.

In addition, the processing blocks 2A, 2C, and 2D have the same configuration as the processing block 2B, except for differences to be described later. Each of the processing blocks 2A, 2C, and 2D is equipped with a main transfer mechanism corresponding to the main transfer mechanism 3B, but instead of “B,” the same alphabetic character as that designated to the processing block having the main transfer mechanism will be used in reference symbol for the main transfer mechanism. Specifically, reference symbol “3A” will be used for the main transfer mechanism in the processing block 2A. Other main transfer mechanisms corresponding to the main transfer mechanism 3B can also transfer the wafer W to the processing module and the shuttle delivery module TRS in the processing block in which the main transfer mechanism is provided, and to the delivery tower adjacent to the processing block in the width direction (Y direction).

For reference symbols of spaces, which correspond to the above-mentioned space 5B and in which shuttles can be provided, the same alphabetic characters as those designated to the processing blocks are used instead of “B.” Further, when a processing block is equipped with a shuttle, the same alphabetic character as that designated to the processing block is also used in reference symbol for that shuttle. Further, the same alphabet character as the processing block in which the shuttle is provided is used for the delivery module TRS for the shuttle. Further, with respect to the shuttle delivery modules TRS for the same shuttle, before the alphabetical characters designated to the processing blocks, “11” is added to reference symbol of a shuttle delivery module on a side of the interface block D4 and “12” is added to reference symbol of a shuttle delivery module on a side of the carrier block D1. As a specific example of the symbol rule described above, the shuttle provided in the processing block 2D is denoted by “4D,” and the delivery modules for the shuttle 4D on the side of the interface block D4 and on the side of the carrier block D1 are denoted by “TRS11D” and “TRS12D,” respectively.

The processing block 2A differs from the processing block 2B in that the transfer region D22 in the processing block 2A is formed across the layer El to the layer E4 in the vertical direction.

The second stacking block D3 has substantially the same configuration as the first stacking block D2. The second stacking block D3 will be described below, focusing on differences from the first stacking block D2.

The processing block 2D of the second stacking block D3 is configured in the same manner as the processing block 2B with respect to the transfer region D22 and the thermal processing region D23. However, developing modules that develop the wafers W by a developing liquid are provided in the layers E5 to E8 included in the upper rotary processing region D21 of the processing block 2D. The processing module stack 23 of the processing block 2D also has a heating module as a thermal processor, and this heating module is for a post exposure bake (PEB) process, for example. The processing module stack 23 of the processing block 2D also has an inspection module that images the wafer W to determine presence or absence of abnormality in the wafer W (i.e., acquires images of the wafer W for inspection).

The space 5D for shuttle in the processing block 2D is located at the same height as the space 5B and in communication with the space 5B. The shuttle 4D and the shuttle delivery modules TRS11B and TRS11D are provided in the space 5D.

The processing block 2C differs from the processing block 2D in that the transfer region D22 in the processing block 2C is formed across the layer El to the layer E4 in the vertical direction.

A delivery tower T2 is provided at an end portion of the transfer region D22 of the second stacking block D3 on a side of the first stacking block D2 (the negative side in the Y direction in FIG. 1 and the like). In a plan view, the delivery tower T2 is positioned so that a portion thereof overlaps with an end portion of the transfer region D22 of the first stacking block D2 on a side of the second stacking block D3 (the positive side in the Y direction in FIG. 1 and the like). The delivery tower T2 is configured such that modules including delivery modules are stacked in multiple stages in the vertical direction.

The interface block D4 has a delivery tower T3 at a central portion thereof in the depth direction (the X direction in FIG. 1). The delivery tower T3 is configured such that modules including delivery modules are stacked in multiple stages in the vertical direction. Transfer mechanisms 31, 32, and 33 are provided on a front side (the negative side in the X direction) of the delivery tower T3, on a rear side (the positive side in the X direction) of the delivery tower T3, and on a side of the exposure apparatus E (the positive side in the Y direction in FIG. 1 and the like), respectively. The transfer mechanisms 31, 32, and 33 are movable vertically and around a vertical axis (θ direction).

A backside cleaning module 35, which supplies a cleaning liquid to a backside of the wafer W to clean the backside of the wafer W, is provided on a front side (the negative side in the X direction) of the transfer mechanism 31. The backside cleaning modules 35 may be stacked vertically in multiple stages. A post-exposure cleaning module 36, which supplies a cleaning liquid to a front surface of the wafer W after exposure, is provided on a rear side (the positive side in the X direction) of the transfer mechanism 32. The post-exposure cleaning module 36 may be stacked vertically in multiple stages. Each of the transfer mechanisms 31 to 33 can transfer the wafer W to the modules in the delivery tower T3. Further, the transfer mechanism 31 can transfer the wafer W to the backside cleaning module 35, the transfer mechanism 32 can transfer the wafer W to the post-exposure cleaning module 36, and the transfer mechanism 33 can transfer the wafer W to the exposure apparatus E.

Here, the shuttles 4B and 4D and the delivery module TRS for each shuttle will be described.

The shuttle 4B transfers the wafer W from the processing block 2D to the carrier block D1. As shown in FIG. 1, of the delivery modules TRS11B and TRS12B for the shuttle 4B, the delivery module TRS12B is provided at an end of the space 5B on a side of the carrier block D1 (the negative side in the Y direction) so that the wafer W can be delivered between the delivery module TRS12B and the transfer mechanism 14 of the carrier block D1. The delivery module TRS11B is provided at an end portion of the space 5D on a side of the processing block 2B (the negative side in the Y direction), and at a location closer to the interface block D4 (on the positive side in the Y direction) than the delivery tower T2, so that the wafer W can be delivered between the delivery module TRS11B and the main transfer mechanism 3D of the processing block 2D.

The shuttle 4D transfers the wafer W from the processing block 2B to the interface block D4. Of the delivery modules TRS11D and TRS12D for the shuttle 4D, the delivery module TRS11D is provided at an end portion of the space 5D on a side of the interface block D4 (the positive side in the Y direction) so that the wafer W can be delivered between the delivery module TRS11D and the transfer mechanism 32 of the interface block D4. The delivery module TRS12D is provided at an end portion of the space 5B on a side of the processing block 2D (the positive side in the Y direction), and at a location closer to the carrier block D1 (on the negative side in the Y direction) than the delivery tower T2, so that the wafer W can be delivered between the delivery module TRS12D and the main transfer mechanism 3B of the processing block 2B.

In addition, the shuttle 4A transfers the wafer W from the processing block 2C to the carrier block D1. The delivery modules TRS11A and TRS12A for the shuttle 4A are disposed at positions similar to those of the delivery modules TRS11B and TRS12B for the shuttle 4B.

Further, the shuttle 4C transfers the wafer W from the processing block 2A to the interface block D4. The delivery modules TRS11C and TRS12C for the shuttle 4C are disposed at positions similar to those of the delivery modules TRS11D and TRS12D for the shuttle 4D.

The coating-and-developing apparatus 1 is also provided with at least one controller 10. The controller 10 processes computer-executable instructions that cause the coating-and-developing apparatus 1 to perform various processes described in the present disclosure. The controller 10 may be configured to control individual components of the coating-and-developing apparatus 1 to perform the various processes described herein. In one embodiment, a part or all of the controller 10 may be included in the coating-and-developing apparatus 1. The controller 10 may include a processor, a memory, and a communication interface. The controller 10 is implemented by, for example, a computer. The processor may be configured to read a program that provides logic or routines for performing various control operations from the memory, and execute the read program to perform the various control operations. The program may be stored in the memory in advance or may be acquired via a medium when needed. The acquired program is stored in the memory, and is read from the memory and executed by the processor.

The medium may be various computer-readable storage media H or a communication line connected to the communication interface. The storage media H may be transitory or non-transitory. The processor may be a central processing unit (CPU) or one or more circuits. The memory may include a random access memory (RAM), a read-only memory (ROM), a hard disk drive (HDD), a solid state drive (SSD), or a combination thereof. The communication interface may communicate with the coating-and-developing apparatus 1 via a communication line such as a local area network (LAN).

The above-described resist film forming module 21 and developing module supply a predetermined processing liquid onto the wafer W by, for example, spin coating. In the spin coating, the processing liquid is discharged onto the wafer W from a discharge nozzle, and the wafer W is held and rotated to spread the processing liquid over a surface of the wafer W. In other words, the resist film forming module 21 and the developing module are rotary processors that hold and rotate substrates for processing.

As shown in FIG. 4, the resist film forming module 21 includes a spin chuck 201 that holds and rotates the wafer W, and a discharge nozzle (not shown) that discharges a processing liquid such as a resist liquid onto the wafer W. The resist film forming module 21 also includes a cup 202 that surrounds the wafer W held on the spin chuck 201 and collects the processing liquid scattered from the wafer W.

The developing module has the same configuration as the resist film forming module, except for the processing liquid discharged from the discharge nozzle.

As shown in FIG. 5, the heating module 24 includes, for example, a hot plate 401 for heating the wafer W, a cooling plate 402 for delivering the wafer W between the hot plate 401 and the main transfer mechanisms 3A to 3D and for cooling the wafer W, a rectifying plate 403 provided above the hot plate 401, and exhausters 404 and 405 for exhausting the transfer region D22 and the heating module 24. A gas exhausted from the exhausters 404 and 405 is discharged to the outside of the coating-and-developing apparatus 1 via the above-described exhaust duct 25.

As shown in FIGS. 1, 3, and 6, the main transfer mechanism 3A includes a vertical guide 301, a horizontal guide 302, and a transfer arm 303.

The vertical guide 301 extends in the vertical direction. For example, the vertical guide 301 is provided at a location adjacent to the transfer region D22 in the depth direction (X direction in the drawings) in a plan view, and among the processing module stacks 23. The vertical guide 301 is provided so as not to interfere with the shuttle 4A and the wafer W transferred to the shuttle 4A. The exhaust duct 25 is provided at a location adjacent to a rear side of the vertical guide 301.

The horizontal guide 302 extends in the width direction (Y direction in the drawings) and move along the vertical guide 301. For example, the horizontal guide 302 is provided at a rear end (on the positive side in the X direction in the drawings) of the transfer region D22.

The transfer arm 303 supports and moves the wafer W. Specifically, the transfer arm 303 holds the wafer W and moves the wafer W horizontally (X and Y directions in the drawings) and around a vertical axis (θ direction).

The transfer arm 303 includes a moving body 311 that moves along the horizontal guide 302, and a base 312 that rotates with respect to the moving body 311. The transfer arm 303 also includes a fork 313. The fork 313 is an example of a substrate support configured to be movable and supports a substrate, and advances and retracts with respect to the base 312. A plurality of forks 313 may be provided in one transfer arm 303.

In addition, the main transfer mechanisms 3B, 3C, and 3D have the same configuration as the main transfer mechanism 3A.

### wafer Processing

Next, an example of wafer processing and a transfer path using the coating-and-developing apparatus 1 will be described.

For example, first, the wafer W is taken out by the transfer mechanism 14 from the carrier C, which is loaded into the carrier block D1 of the coating-and-developing apparatus 1 and placed on the mounting plate 12, and then is transferred to the delivery module of the delivery tower T1.

Subsequently, the wafer W is transferred by the transfer mechanism 16 to the hydrophobilizing module 15, and is subjected to a hydrophobilizing process. Thereafter, the wafer W is returned to the delivery tower T1 by the transfer mechanism 16.

Subsequently, the wafer W is transferred by the main transfer mechanism 3A or 3B to the resist film forming module 21, and a resist film is formed on the wafer W.

Specifically, first, operations of the transfer arm 303 of the main transfer mechanism 3A or 3B is controlled by the controller 10 to transfer the wafer W to the resist film forming module 21.

More specifically, the fork 313 supporting the wafer W is moved from a standby position on a side of a base end thereof to a delivery position over the spin chuck 201 of the resist film forming module 21. Hereinafter, for the sake of simplicity of explanation, it is assumed that a position of the wafer W on the fork 313, that is, a positional relationship between the fork 313 and the wafer W supported on the fork 313, is always the same.

After the fork 313 is moved to the delivery position, lift pins (not shown) in the resist film forming module 21 are raised, and the wafer W is delivered onto the lift pins. The fork 313 is then returned to the standby position, and the lift pins are lowered. Thus, the wafer Wis delivered to and held by the spin chuck 201 of the resist film forming module 21.

Further, a resist liquid is discharged from the discharge nozzle onto the wafer W being rotated by the spin chuck 201, and a resist film is formed on the wafer W.

After the resist film is formed, an edge bead removal (EBR) process is performed by the same resist film forming module 21.

Specifically, a removal liquid such as a solvent is discharged from the discharge nozzle onto the wafer W being rotated by the spin chuck 201, and the resist film on a peripheral edge portion of the wafer W is removed in an annular shape centered at the wafer W.

Thereafter, the wafer W is transferred by the main transfer mechanism 3A or 3B to the heating module 24 in the first stacking block, and the wafer W is subjected to a pre-baking process. Subsequently, the wafer W is transferred by the main transfer mechanism 3A or 3B to the delivery module of the delivery tower T2, and is transferred by the main transfer mechanism 3C or 3D to the delivery module of the delivery tower T3 of the interface block D4. In addition, the wafer W after the resist film formation may be transferred from the processing block 2A to the delivery tower T3, while bypassing the second stacking block D3, via the main transfer mechanism 3A, the shuttle 4C, the delivery modules TRS12C and TRS11C, and the transfer mechanism 32. Further, the wafer W after the resist film formation may be transferred from the processing block 2B to the delivery tower T3, while bypassing the second stacking block D3, via the main transfer mechanism 3B, the shuttle 4D, the delivery modules TRS12D and TRS11D, and the transfer mechanism 32.

Subsequently, the wafer W is transferred by the transfer mechanism 31 to the backside cleaning module 35, and the backside of the wafer W is cleaned. Thereafter, the wafer W is returned to the delivery tower T3 by the transfer mechanism 31, and then is transferred by the transfer mechanism 33 to the exposure apparatus E. Thus, the wafer W is subjected to an exposure process. The wafer W after the exposure is returned to the delivery tower T3 by the transfer mechanism 33, and then is transferred by the transfer mechanism 32 to the post-exposure cleaning module 36. Thus, the wafer W is cleaned.

The wafer W after the cleaning by the post-exposure cleaning module 36 is, for example, first returned to the delivery tower T3 by the transfer mechanism 32. Thereafter, the wafer Wis transferred by the main transfer mechanism 3C or 3D sequentially to the heating module, the developing module, and the inspection module in the second stacking block D3. Thus, a resist pattern is formed after a PEB (Post Exposure Bake) process, and then, presence or absence of abnormality is determined. Subsequently, the wafer W is returned to the delivery tower T2 by the main transfer mechanism 3C or 3D, and then is returned to the delivery tower T1 by the main transfer mechanism 3A or 3B. In addition, the wafer W processed by the inspection module may be returned from the processing block 2C to the delivery tower T1, while bypassing the first stacking block D2, via the main transfer mechanism 3C, the shuttle 4A, the delivery modules TRS11A and TRS12A, and the transfer mechanism 16. Further, the wafer W processed by the inspection module may be returned from the processing block 2D to the delivery tower T1, while bypassing the first stacking block D2, via the main transfer mechanism 3D, the shuttle 4B, the delivery modules TRS11B and TRS12B, and the transfer mechanism 16.

Thereafter, the wafer W is returned from the delivery tower T1 to the carrier C by the transfer mechanism 14.

This completes a series of wafer processing steps.

### History of Reaching Technique of Present Disclosure

The aforementioned delivery position is pre-adjusted, for example, at a star-up time of an apparatus, so that when an EBR process is performed by using the coating-and-developing apparatus 1 described above, a removal width of the resist film by the EBR process becomes uniform in a circumferential direction of the wafer W.

However, even with the pre-adjustment described above, when a setting of a processing temperature of the heating module 24 (e.g., a temperature of the hot plate 401) is changed, the removal width of the resist film by the EBR process may become non-uniform after the change. That is, the wafer W on the fork 313 moved to the delivery position may become eccentric with respect to the spin chuck 201. The reason for this eccentricity is as follows.

For example, a length of the vertical guide 301 changes due to influence of heat from the heating module 24, specifically, influence of heat from the exhaust duct 25 and the like. Thus, as indicated by an imaginary line in FIG. 6, the vertical guide 301 is deformed and warped. As a result, the position of the fork 313 is shifted, which causes the above-mentioned eccentricity.

As a result of extensive research, the inventors have found that after a change in setting of the processing temperature in the heating module 24, a direction in which the wafer W on the fork 313 moved to the delivery position shifts during a predetermined period of time (hereinafter also referred to as a “wafer shift direction”) changes according to an elapsed time after the setting is changed. A reason for generation of this change is, for example, as follows. That is, since structures of the coating-and-developing apparatus lon one side and the other side of the vertical guide 301 in the width direction (the Y direction in FIG. 1 and the like) differ from each other in terms of heat capacity and maximum attainable temperature, warpage of the vertical guide 301 viewed from the width direction changes over time. As a result, the position of the fork 313 changes over time, and it is considered that the wafer shift direction changes according to the elapsed time.

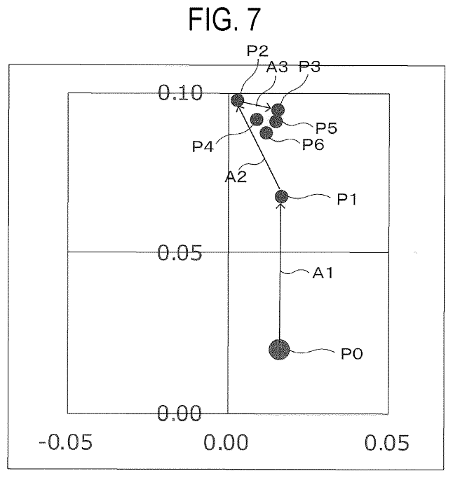

FIG. 7 is a diagram showing changes in the wafer shift direction according to an elapsed time after a setting of the processing temperature in the heating module 24 is changed.

Points P0 to P6 in FIG. 7 sequentially indicate, by using a center position of the spin chuck 201 as a reference, center positions of the wafer W on the fork 313 moved to the delivery position when the elapsed time is 0 hours, 1.5 hours, 3 hours, 4.5 hours, 6 hours, and 7.5 hours, respectively. The horizontal and vertical axes in FIG. 7 represent amounts of shift in the width direction (the Y direction in FIG. 1 and the like) and in the depth direction (the X direction in FIG. 1 and the like) of the coating-and-developing apparatus 1, respectively, in millimeters.

As shown in FIG. 7, while the elapsed time changes from 0 hours (point P0) to 1.5 hours (point P1), the position of the wafer W on the fork 313 moved to the delivery position changes almost only in the depth direction (corresponding to the vertical axis direction in FIG. 7) of the coating-and-developing apparatus 1. In contrast, while the elapsed time changes from 1.5 hours (point P1) to 3 hours (point P2), the position of the wafer W changes in both the depth direction and the width direction (corresponding to the horizontal axis direction in FIG. 7) of the coating-and-developing apparatus 1. Further, while the elapsed time changes from 3 hours (point P2) to 4.5 hours (point P3), the position of the wafer W changes mainly in the width direction of the coating-and-developing apparatus 1.

In addition, as a result of extensive research, the inventors have found that the wafer shift direction has reproducibility, as well as it changes with the elapsed time after the setting is changed as described above.

In addition, as a result of extensive research, the inventors have found that an amount of shift of the wafer W on the fork 313 moved to the delivery position during a predetermined period of time (hereinafter also referred to as a “wafer shift amount”) after the setting of the processing temperature in the heating module 24 is changed corresponds to an amount of change in an atmospheric temperature in the heating module 24 during the predetermined period of time.

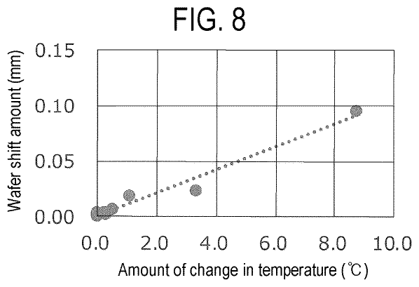

FIG. 8 is a diagram showing correspondence of the wafer shift amount to the amount of change in the atmospheric temperature in the heating module 24 during a predetermined period of time.

In FIG. 8, the horizontal axis represents an amount of change in temperature measured by a temperature sensor attached to an inner wall of a housing (not shown) of the heating module 24 on a side of the cooling plate 402, that is, the atmospheric temperature in the heating module 24, during the predetermined period of time. The vertical axis represents the wafer shift amount.

As shown in FIG. 8, the wafer shift amount is approximately in direct proportion to the amount of change in the atmospheric temperature in the heating module 24 during the predetermined period of time.

Adjustment of the delivery position, which will be described later, is based on the findings described above.

### Controller 10

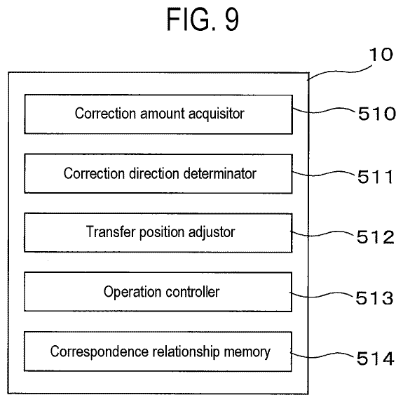

FIG. 9 is a functional block diagram of the controller 10, and is a functional block diagram relating to transfer of the wafer W to the resist film forming module 21 as a rotary processor.

As shown in FIG. 9, the controller 10 according to the present embodiment includes a correction amount acquisitor 510, a correction direction determinator 511, a delivery position adjustor 512, and an operation controller 513, which are implemented by reading and executing the program stored in the memory by the aforementioned processor. The controller 10 further includes a correspondence relationship memory 514. The correction amount acquisitor 510, the correction direction determinator 511, and the delivery position adjustor 512 are for adjusting the delivery position. Adjusting the delivery position is performed for each resist film forming module 21 and each transfer arm 303. However, in the following description, adjusting the delivery position only for one resist film forming module 21 by the transfer arm 303 of the main transfer mechanism 3A will be described.

The correction amount acquisitor 510 acquires a correction amount of the delivery position when the setting of the processing temperature in the heating module 24 is changed.

Specifically, when the setting of the processing temperature in the heating module 24 in the processing block 2A is changed, the correction amount acquisitor 510 determines and acquires the correction amount of the delivery position based on an amount of change in the temperature of the exhaust duct 25, which corresponds to the atmospheric temperature in the heating module 24, during a predetermined period of time.

More specifically, when the setting of the processing temperature in the heating module 24 in the processing block 2A is changed, the correction amount acquisitor 510 acquires an amount of change T1 in the temperature of the exhaust duct 25 of the processing block 2A during a predetermined period of time t1 based on a measurement result by the temperature sensor 26, every time the predetermined period of time t1 elapses. The predetermined period of time t1 is, for example, 1.5 hours.

Further, every time the predetermined period of time t1 elapses, the correction amount acquisitor 510 calculates (i.e., determines) a correction amount L1 of the delivery position based on a first correspondence relationship (information on the first correspondence relationship) pre-stored in the correspondence relationship memory 514 and an acquired amount of change ΔT1 in the temperature of the exhaust duct 25 of the processing block 2A during the predetermined period of time t1. The first correspondence relationship (information on the first correspondence relationship) is a correspondence relationship (information on the correspondence relationship) between the amount of change ΔT in the temperature of the exhaust duct 25 during the predetermined period of time t1 and a correction amount L of the delivery position. Specifically, the first correspondence relationship (information on the first correspondence relationship) is, for example, information on an intercept a in an equation (L=a*ΔT) that calculates the correction amount L of the delivery position from the amount of change ΔT in the temperature during the predetermined period of time t1.

The first correspondence relationship is acquired, for example, as follows. That is, first, a correspondence relationship between the amount of change in the atmospheric temperature in the heating module 24 during the predetermined period of time and the wafer shift amount, as shown in FIG. 8, specifically, for example, a correspondence relationship between the amount of change in the temperature in the exhaust duct 25 during the predetermined period of time ΔT and the wafer shift amount, is acquired. Further, the first correspondence relationship is acquired by considering the wafer shift amount in the correspondence relationship as the correction amount L of the delivery position.

When the setting of the processing temperature in the heating module 24 is changed, the correction direction determinator 511 determines a correction direction of the delivery position according to an elapsed time after the setting is changed.

Specifically, when the setting of the processing temperature in the heating module 24 in the processing block 2A is changed, the correction direction determinator 511 determines a correction direction θ2 of the delivery position based on a second correspondence relationship (information on the second correspondence relationship) pre-stored in the correspondence relationship memory 514 and an elapsed time t2 at a time of adjusting the delivery position.

The second correspondence relationship (information on the second correspondence relationship) is a correspondence relationship (information on the correspondence relationship) between an elapsed time t and a correction direction θ of the delivery position.

More specifically, when the setting of the processing temperature in the heating module 24 in the processing block 2A is changed, the correction direction determinator 511 determines the correction direction θ2 of the delivery position every time the predetermined period of time t1 elapses, based on the second correspondence relationship (information on the second correspondence relationship) pre-stored in the correspondence relationship memory 514 and the elapsed time t2 (t2=n*t1, where n is a natural number) at the time of adjusting the delivery position.

The second correspondence relationship is acquired, for example, as follows. That is, first, a relationship between the elapsed time t after the setting of the processing temperature in the heating module 24 is changed and a position of the wafer W on the fork 313 moved to the delivery position, as shown in FIG. 7, is acquired. Thereafter, from the acquisition result, a correspondence relationship between the elapsed time t and a wafer shift direction θ′ is acquired. Further, the second correspondence relationship is acquired by reversing positive and negative signs of the wafer shift direction θ′ in the correspondence relationship to obtain the correction direction θ of the delivery position.

When the setting of the processing temperature in the heating module 24 is changed, the delivery position adjustor 512 adjusts the delivery position based on the delivery position correction amount L1 acquired by the correction amount acquisitor 510 and the correction direction θ2 determined by the correction direction determinator 511.

Specifically, when the setting of the processing temperature in the heating module 24 in the processing block 2A is changed, the delivery position adjustor 512 calculates an adjusted delivery position every time the predetermined period of time t1 elapses, based on the acquired delivery position correction amount L1 and the determined correction direction θ2.

More specifically, when the setting of the processing temperature in the heating module 24 in the processing block 2A is changed, the delivery position adjustor 512 obtains the adjusted delivery position every time the predetermined period of time t1 elapses by adding L1*cosθ2 to an x-coordinate of the delivery position before adjustment and adding L1*sinθ2 to a y-coordinate of the delivery position before adjustment.

The operation controller 513 controls operations of the transfer arm 303. For example, after calculating the adjusted delivery position, the operation controller 513 controls an operation of the transfer arm 303 to move the fork 313 from the aforementioned standby position to the adjusted delivery position.

The correspondence relationship memory 514 stores in advance the first correspondence relationship, the second correspondence relationship, and the like before adjusting the delivery position.

### Flow of Adjusting Delivery Position

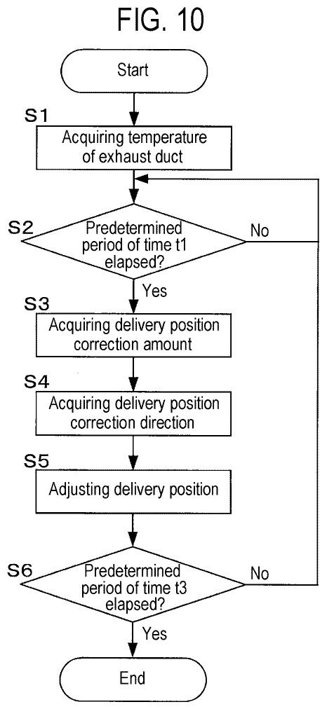

FIG. 10 is a flowchart illustrating an example of a flow of adjusting a delivery position.

When the setting of the processing temperature in any heating module 24 in the processing block 2A is changed, as shown in FIG. 10, the correction amount acquisitor 510 first acquires the temperature of the exhaust duct 25 at that time (i.e., immediately after the setting is changed), which is measured by the temperature sensor 26 in the processing block 2A (Step S1).

Subsequently, the correction amount acquisitor 510 determines whether or not a predetermined period of time t1 has elapsed after the setting is changed (Step S2).

When it is determined that the predetermined period of time t1 has not elapsed (“No” in Step S2), the flow returns to Step S2.

On the other hand, when it is determined that the predetermined period of time t1 has elapsed (“Yes” in Step S2), the correction amount acquisitor 510 acquires the correction amount L1 of the delivery position (Step S3).

Specifically, the correction amount acquisitor 510 first acquires the amount of change ΔT1 in the temperature of the exhaust duct 25 during the predetermined period of time t1, which is measured by the temperature sensor 26 in the processing block 2A.

More specifically, the correction amount acquisitor 510 first acquires the temperature of the exhaust duct 25 at that time, which is measured by the temperature sensor 26 in the processing block 2A. Based on this acquisition result and the acquisition result in Step S1, the correction amount acquisitor 510 acquires the amount of change ΔT1 in the temperature of the exhaust duct 25 during the predetermined period of time t1, which is measured by the temperature sensor 26 in the processing block 2A.

Further, the correction amount acquisitor 510 calculates and acquires the correction amount L1 of the delivery position based on the first correspondence relationship (information on the first correspondence relationship) pre-stored in the correspondence relationship memory 514 and the acquired amount of change ΔT1 in the temperature of the exhaust duct 25 during the predetermined period of time t1.

Further, the correction direction determinator 511 determines the correction direction θ2 of the delivery position according to the elapsed time t2 after the setting is changed (Step S4).

Specifically, the correction direction determinator 511 determines the correction direction θ2 of the delivery position based on the second correspondence relationship (information on the second correspondence relationship) pre-stored in the correspondence relationship memory 514 and the elapsed time t2 at this point of time (at the time of adjusting the delivery position) after the setting is changed.

In addition, the order of Steps S3 and S4 does not matter.

Thereafter, the delivery position adjustor 512 adjusts the delivery position based on the delivery position correction amount L1 acquired in Step S3 and the delivery position correction direction θ2 determined in Step S4, that is, acquires the adjusted delivery position (Step S5).

Subsequently, the delivery position adjustor 512 determines whether or not a predetermined period of time t3 (>t1) has elapsed after the setting is changed (Step S6). The predetermined period of time t3 is, for example, 7.5 hours.

When it is determined that the predetermined period of time t3 has not elapsed (“No” in Step S6), the flow returns to Step S2. However, in the flow that returns to Step S2 via Steps S3 to S5, it is determined in Step S2 whether or not a further predetermined period of time t1 has elapsed after it was determined that the predetermined period of time t1 had elapsed previously. In addition, in the flow that returns to Step S2 via Steps S3 to S5, the amount of change ΔT1 in the temperature during the predetermined period of time t1 is obtained in step S3 by using measurement results of the temperature of the exhaust duct 25, which are acquired by the temperature sensor 26 in the processing block 2A in the current step S3 and in the previous step S3. Further, in the flow that returns to Step S2 via Steps S3 to S5, the adjusted delivery position acquired in the previous Step S5 is further adjusted in step S5.

On the other hand, when it is determined in Step S6 that the predetermined period of time t3 has elapsed after the setting is changed (“Yes” in Step S6), the temperature of the exhaust duct 25, that is, the atmospheric temperature in the heating module 24, has stabilized, and further adjustment of the delivery position is not necessary. Thus, the series of flow of adjusting the delivery position ends.

For example, each of the adjusted delivery positions sequentially acquired in Step S5 before the end of the adjustment flow is used after the adjusted delivery position is acquired and before a next adjusted delivery position is acquired.

In addition, wafer processing may be suspended after the adjustment flow is started and before the adjustment flow ends, and may be started after the adjustment flow ends by using a lastly acquired adjusted delivery position.

When the setting of the processing temperature in the heating module 24 in the processing block 2A is changed, the above-mentioned adjustment is performed individually for each resist film forming module 21 in the processing block 2A. Further, the correspondence relationship between the elapsed time t and the correction direction θ, which is acquired in advance individually for each resist film forming module 21, is used to determine the correction direction θ2 in this individual adjustment. Similarly, the correspondence relationship between the change ΔT and the correction amount L, which is acquired in advance individually for each resist film forming module 21, is used to calculate the correction amount L in this individual adjustment.

### Major Operative Effects of Present Embodiment

In the present embodiment, by using the fact that the wafer shift direction changes according to the elapsed time after the setting of the processing temperature in the heating module 24 is changed, the controller 10 adjusts the delivery position by the correction direction determinator 511 and the delivery position adjustor 512 based on the correction direction θ2 according to the elapsed time. Therefore, by using an appropriate correction amount of the delivery position, in addition to the correction direction θ2, when adjusting the delivery position, it is possible to suppress eccentricity of the wafer W on the fork 313, which has been moved to the adjusted delivery position, with respect to the spin chuck 201. That is, according to the present embodiment, even when the setting of the processing temperature in the heating module 24 is changed, it is possible to transfer the wafer W to a target position on the spin chuck 201 with high accuracy.

Further, in the present embodiment, the controller 10 adjusts the delivery position by also using the fact that the wafer shift amount corresponds to the amount of change in the atmospheric temperature in the heating module 24 during the predetermined period of time.

Specifically, the controller 10 adjusts the delivery position by the correction amount acquisitor 510, the correction direction determinator 511, and the delivery position adjustor 512, based on the delivery position correction amount L1 corresponding to the amount of change ΔT1 in the temperature of the exhaust duct 25, which corresponds to the atmospheric temperature in the heating module 24, during the predetermined period of time, and the correction direction 02 according to the elapsed time. Therefore, it is possible to suppress eccentricity of the wafer W on the fork 313, which has been moved to the adjusted delivery position, with respect to the spin chuck 201. That is, according to the present embodiment, even when the setting of the processing temperature in the heating module 24 is changed, it is possible to transfer the wafer W to the target position on the spin chuck 201 with high accuracy.

### Another Example of Position Relating to Thermal Processing in Heating Module 24

In the above example, the position relating to the thermal processing in the heating module 24 is the exhaust duct 25, but the relating position may also be a position in the housing of the heating module 24, specifically, for example, a position in the housing on a side of the cooling plate 402. That is, the temperature sensor 26 may be provided on the inner wall of the housing of the heating module 24 on a the side of the cooling plate 402.

When the position relating to the thermal processing in the heating module 24 is a position in the housing of the heating module 24, the following may also be applicable. That is, when the setting of the processing temperature in any one of the heating modules 24 in the processing block 2A is changed, the amount of change ΔT1 in the temperature measured by the temperature sensor 26 of the one heating module with the changed setting may be used to calculate the delivery position correction amount L1 during the predetermined period of time t1. Further, when the setting of the processing temperature in any one of the heating modules 24 in the processing block 2A is changed, the amount of change ΔT1 in the temperature measured by the temperature sensor 26 of each of the plurality of heating modules 24 including the one heating module 24 during the predetermined period of time t1 may be used to calculate the delivery position correction amount L1. In this case, an amount of change ΔT1 in a total value (accumulated value) of the temperatures measured by the temperature sensors 26 of the plurality of heating modules 24 during the predetermined period of time t1 may be used to calculate the delivery position correction amount L1.

### Modification of Coating-and-Developing Apparatus

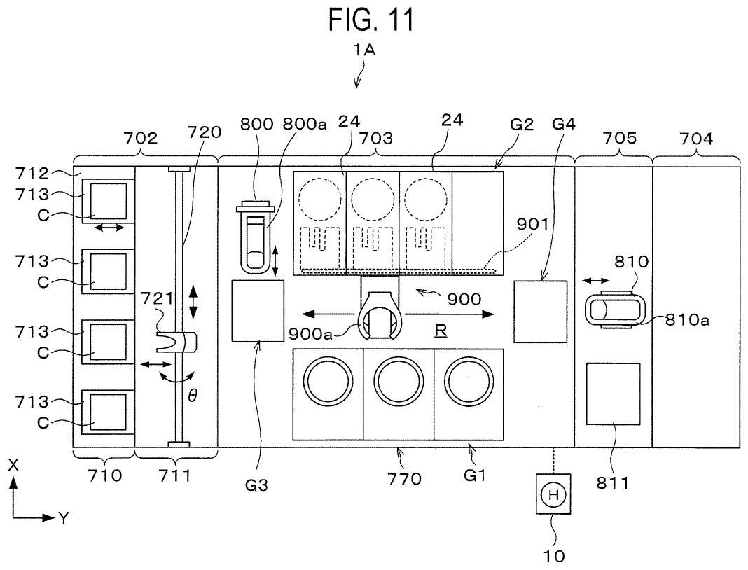

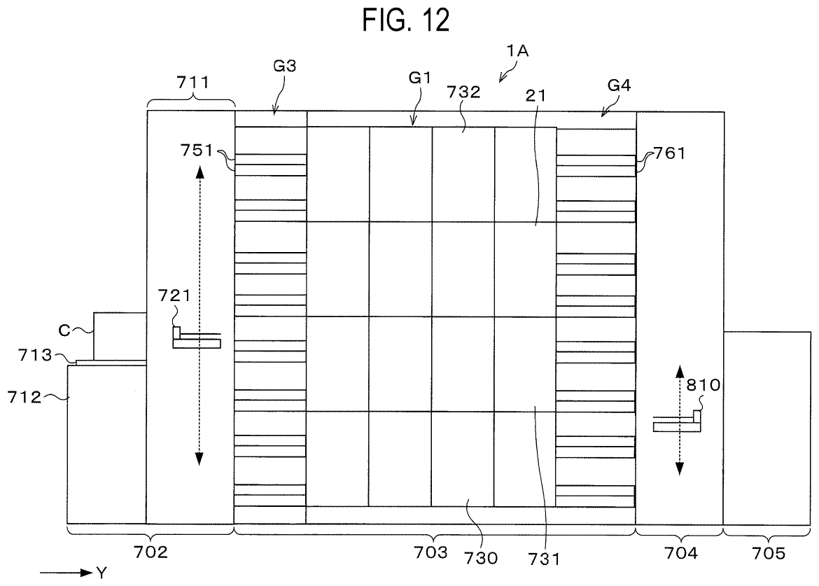

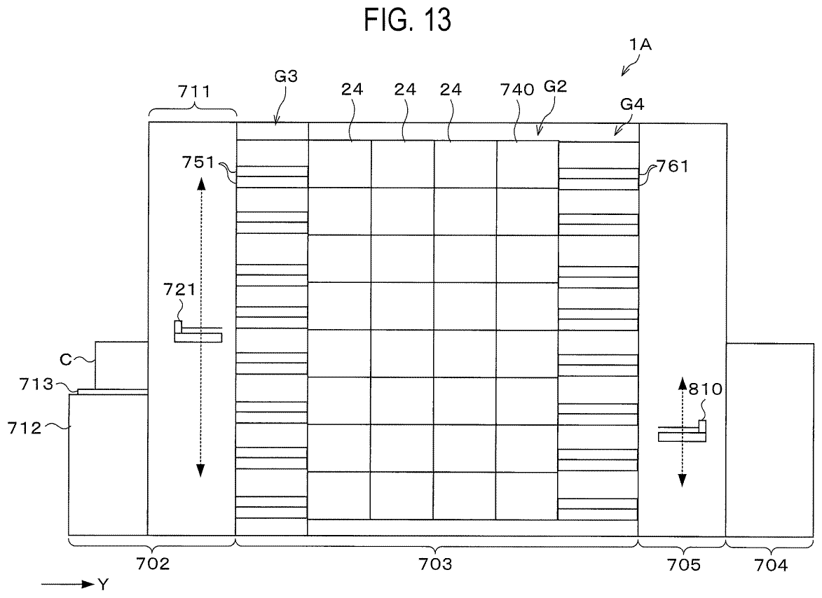

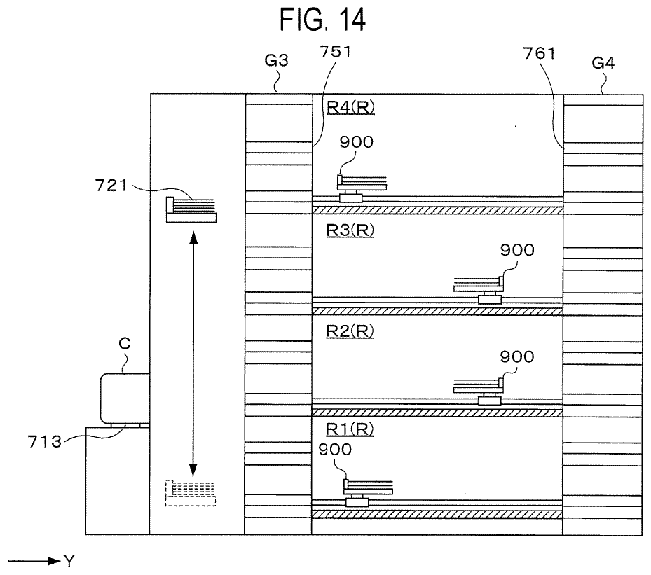

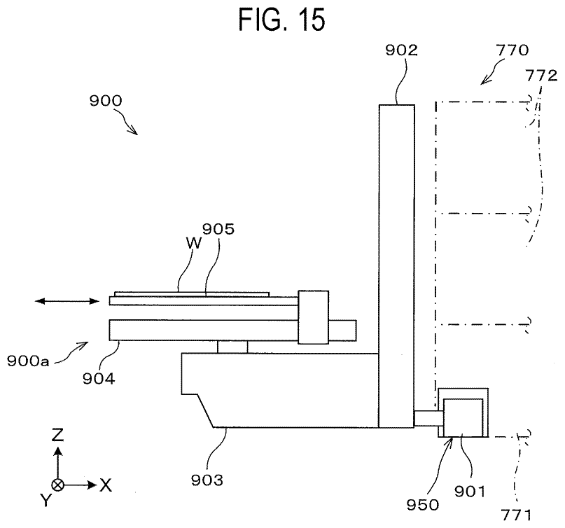

FIG. 11 is a plan view showing a schematic configuration of a modification of the coating-and-developing apparatus including the substrate transfer apparatus according to the present embodiment. FIGS. 12 and 13 are views showing schematic internal configurations of a front side and a rear side of the coating-and-developing apparatus, respectively. FIG. 14 is a longitudinal cross-sectional side view showing a schematic internal configuration of the coating-and-developing apparatus. FIG. 15 is a side view of a transfer mechanism which will be described later.

As shown in FIGS. 11 to 13, a coating-and-developing apparatus 1A includes a carrier station 702 configured to load and unload carriers C with respect to the outside, and a processing station 703 provided with a variety of processing modules for performing predetermined processes such as resist film forming process. The coating-and-developing apparatus 1A also includes an interface station 705 located adjacent to the processing station 703 on a positive side in a Y direction (right-hand side in FIG. 11) and configured to deliver the wafer W between the processing station 703 and an exposure apparatus 704. The carrier station 702, the processing station 703, and the interface station 705 are all integrally connected.

The carrier station 702 is divided into, for example, a carrier loader/unloader 710 and a wafer transferer 711. For example, the carrier loader/unloader 710 is located at an end portion of the coating-and-developing apparatus 1A on a negative side in the Y direction (left-hand side in FIG. 11). A carrier stage 712 is provided in the carrier loader/unloader 710. A plurality of (e.g., four) mounting plates 713 are provided on the carrier stage 712. The mounting plates 713 are arranged side-by-side in a row in the horizontal X direction (a vertical direction in FIG. 11). The mounting tables 713 can place carriers C thereon when the carriers C are loaded and unloaded with respect to the outside of the coating-and-developing apparatus 1A.

A transfer apparatus 721 that can move on a transfer path 720 extending in the X direction (the vertical direction in FIG. 11) is provided in the wafer transferer 711. The transfer apparatus 721 is also movable vertically and around a vertical axis (the θ direction), and can transfer the wafer W between carriers C on each mounting plate 713 and a delivery module in a third block G3 of the processing station 703, which will be described later.

A plurality of, e.g., first to fourth blocks G1, G2, G3, and G4, each equipped with various modules is provided in the processing station 703. For example, the first block G1 is provided on a front side of the processing station 703 (a negative side in the X direction in FIG. 11), and the second block G2 is provided on a rear side of the processing station 703 (a positive side in the X direction in FIG. 11). The third block G3 is provided in the processing station 703 on a side of the carrier station 702 (the negative side in the Y direction in FIG. 11), and the fourth block G4 is provided in the processing station 703 on a side of the interface station 705 (the positive side in the Y direction in FIG. 11).

As shown in FIG. 12, the first block G1 includes, sequentially from bottom, a plurality of liquid processing modules, such as a developing module 730, a lower anti-reflective film forming module 731 that forms an anti-reflective film below the resist film on the wafer W (hereinafter referred to as a “lower anti-reflective film”), a resist film forming module 21, and an upper anti-reflective film forming module 732 that forms an anti-reflective film above the resist film on the wafer W (hereinafter referred to as an “upper anti-reflective film”).

For example, each of the developing module 730, the lower anti-reflective film forming module 731, the resist film forming module 21, and the upper anti-reflective film forming module 732 includes four modules arranged side by side in the horizontal direction. The numbers and arrangement of the developing modules 730, the lower anti-reflective film forming modules 731, the resist film forming modules 21, and the upper anti-reflective film forming modules 732 may be selected arbitrarily.

For example, in the second block G2, as shown in FIG. 13, heating modules 24 and adhesion modules 740 for improving adhesion of a resist liquid to the wafer W are arranged side by side in the vertical direction and the like. The numbers and arrangement of the heating modules 24 and adhesion modules 740 may also be selected arbitrarily.

For example, in the third block G3, a plurality of delivery modules 751 are provided sequentially from bottom. Further, in the fourth block G4, a plurality of delivery modules 761 are arranged sequentially from bottom.

As shown in FIG. 11, a transfer region R is formed in a region surrounded by the first block G1 to the fourth block G4. A region, i.e., the first block G1, where rotary processors such as the resist film forming modules 21 is provided, and a region, i.e., the second block G2, where thermal processors such as the heating modules 24 and the adhesion modules 740 are provided face each other via the transfer region R.

Further, a wafer transfer module 800 is provided adjacent to the third block G3 on the positive side in the X direction. The wafer transfer module 800 has a transfer arm 800a that is movable, for example, in the X direction, the θ direction, and the vertical direction. The wafer transfer module 800 moves vertically while supporting the wafer W by the transfer arm 800a, and can transfer the wafer W to each delivery module in the third block G3.

A wafer transfer module 810 and a delivery module 811 are provided in the interface station 705. The wafer transfer module 810 has a transfer arm 810a that is movable, for example, in the Y direction, the θ direction, and the vertical direction. The wafer transfer module 810 supports the wafer W, for example, on the transfer arm 810a, and can transfer the wafer W among each delivery module in the fourth block G4, the delivery module 811, and the exposure apparatus 704.

The transfer region R will be further explained. As shown in FIG. 14, the transfer region R is configured by stacking four transfer regions R1 to R4 sequentially from bottom, and each of the transfer regions R1 to R4 is formed to extend in a direction from the third block G3 toward the fourth block G4 (the Y direction in the drawings). A liquid processing module such as the resist film forming module 21 is disposed on one side of the transfer regions R1 to R4 in the width direction (the X direction in the drawing), and the heating module 24, for example, is disposed on the other side.

Further, a transfer arm 900a of a transfer mechanism 900, which serves as the substrate transfer apparatus according to the present disclosure, is provided in each of the transfer regions R1 to R4. The transfer mechanism 900 transfers the wafer W to a module (such as the resist film forming module 21) adjacent to a transfer region among the transfer regions R1 to R4, in which the transfer mechanism 900 is located.

Further, as shown in FIG. 11, the processing station 703 of the coating-and-developing apparatus 1A includes a housing 770. The housing 770 accommodates each of the modules described above. The housing 770 is also partitioned into the transfer regions R. As shown in FIG. 15, the housing 770 includes a housing 771 that accommodates a guide 901 and the like, which will be described later.

As shown in FIGS. 11 and 15, the transfer mechanism 900 includes the guide 901 extending in a length direction (the Y direction in FIG. 15 and the like) of the transfer regions R1 to R4, and the transfer arm 900a that supports and moves the wafer W in the horizontal direction (the X and the Y directions in the drawings), the vertical direction, and around a vertical axis (the θ direction).

The transfer arm 900a includes a frame 902 that moves along the guide 901, an elevator 903 that moves up and down along the frame 902, and a base 904 that rotates with respect to the elevator 903. The transfer arm 900a also includes a fork 905. The fork 905 is configured movably, supports the wafer W, and advances and retracts with respect to the base 904.

Further, the transfer mechanism 900 includes a drive mechanism (not shown) that linearly moves the fork 905 in an advancing/retracting direction (the X direction in the drawings) with respect to the base 904, and a drive mechanism (not shown) that rotates the base 904 with respect to the elevator 903, that is, moves the base 904 in the θ direction. The transfer mechanism 900 also includes a drive mechanism (not shown) that raises and lowers the elevator 903 along the frame 902, and a drive mechanism 950 that moves the frame 902 along the guide 901.

The drive mechanism 950 includes the aforementioned guide 901, and further includes an actuator (not shown) such as a motor as a drive source that generates a driving force to move the frame 902 along the guide 901. The drive mechanism 950 is accommodated in the aforementioned housing 771. A housing 772 that accommodates the hot plate 401 of the heating module 24 and the like is stacked on top of the housing 771.

In the coating-and-developing apparatus 1A having the above-described transfer mechanism 900, when the setting of the processing temperature in the heating module 24 is changed, the housing 771 accommodating the guide 901 of the transfer mechanism 900 may thermally contract due to influence of the hot plate 401, which may result in deformation of the guide 901. As a result, the wafer W on the fork 905 moved to the delivery position may become eccentric with respect to the spin chuck 201 of the resist film forming module 21.

The method of adjusting the delivery position disclosed herein is also applicable to the delivery position of the fork 905 with respect to the resist film forming module 21.

According to the present disclosure in some embodiments, it is possible to transfer a substrate to a target position with high precision.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

In addition, the effects described in the present specification are merely descriptive or exemplary and are not restrictive. In other words, the technique disclosed herein may exhibit other effects that will be apparent to those skilled in the art from the description of the present specification, in addition to or in place of the above effects.

In addition, the following configuration examples also fall within the technical scope of the present disclosure.

(1) A substrate transfer apparatus for transferring a substrate to a rotary processor, which is provided in a common housing with a thermal processor for performing thermal processing on the substrate and configured to hold and rotate the substrate for processing, the apparatus including:
a transfer arm that supports and moves the substrate; and
a controller that controls an operation of the transfer arm,
wherein the controller performs:
   when a setting of a processing temperature in the thermal processor is changed,
   acquiring a correction amount of a delivery position, which is a position of the transfer arm when the substrate is delivered to the rotary processor;
   determining a correction direction of the delivery position according to an elapsed time after the setting is changed; and
   adjusting the delivery position based on the acquired correction amount and the determined correction direction.

(2) The substrate transfer apparatus of (1), further including a measurer that measures a temperature at a position relating to the thermal processing in the thermal processor, wherein the controller acquires the correction amount of the delivery position according to an amount of change in temperature at the relating position measured by the measurer during a predetermined period of time.

(3) The substrate transfer apparatus of (2), further including a memory that pre-stores a correspondence relationship between the amount of change in temperature at the relating position during the predetermined period of time and the correction amount of the delivery position,
wherein the controller acquires the correction amount of the delivery position based on the amount of change in the measured temperature at the relating position during the predetermined period of time and the pre-stored correspondence relationship.

(4) The substrate transfer apparatus of any one of (1) to (3), further including a memory that pre-stores a correspondence relationship between the elapsed time and the correction direction of the delivery position,
wherein the controller determines the correction direction of the delivery position based on the elapsed time at a time of adjusting the delivery position and the pre-stored correspondence relationship.

(5) A substrate processing apparatus, wherein a rotary processing region where a rotary processor is provided and a thermal processing region where a thermal processor is provided faces each other via a transfer region where the transfer arm of the substrate transfer apparatus of any one of (1) to (3) is provided,
wherein the substrate transfer apparatus further includes a guide that extends in a predetermined direction to guide movement of the transfer arm, and
wherein the guide is provided in the thermal processing region.

(6) A substrate processing apparatus, wherein a rotary processing region where a rotary processor is provided and a thermal processing region where a thermal processor is provided face each other via a transfer region where the transfer arm of the substrate transfer apparatus of (2) or (3) is provided,
wherein the substrate transfer apparatus further includes a guide that extends in a predetermined direction to guide movement of the transfer arm,
wherein the guide is provided in the thermal processing region, and
wherein the relating position is an exhaust duct connected to the thermal processor.

(7) The substrate processing apparatus of (6), wherein the exhaust duct is provided at a position in the thermal processing region, the position being among a plurality of thermal processors and on an opposite side of the guide to the rotary processor.

(8) The substrate processing apparatus of any one of (5) to (7), wherein a plurality of rotary processors is provided in the rotary processing region, and
wherein the controller determines the correction direction of the delivery position individually for each of the rotary processors and adjusts the delivery position based on the determined correction direction.

(9) A substrate transfer method including transferring a substrate to a rotary processor by using a transfer arm, wherein the rotary processor is provided in a common housing with a thermal processor for performing thermal processing on the substrate and configured to hold and rotate the substrate for processing,
wherein the transferring the substrate includes:
   when a setting of the processing temperature in the thermal processor is changed,
   acquiring a correction amount of a delivery position, which is a position of the transfer arm when the substrate is delivered to the rotary processor;
   determining a correction direction of the delivery position according to an elapsed time after the setting is changed; and
   adjusting the delivery position based on the acquired correction amount and the determined correction direction.

(10) The substrate transfer method of (9), wherein the adjusting the delivery position includes acquiring the correction amount of the delivery position according to an amount of change in temperature measured by a measurer at a position relating to the thermal processing in the thermal processor during a predetermined period of time.

(11) The substrate transfer method of (10), wherein the acquiring the correction amount includes determining the correction amount of the delivery position based on a pre-stored correspondence relationship between the amount of change in temperature at the relating position during the predetermined period of time and the correction amount for the delivery position, and the amount of change in the measured temperature at the relating position during the predetermined period of time.

(12) The substrate transfer method of any one of (9) to (11), wherein the adjusting the delivery position includes determining the correction direction of the delivery position based on a pre-stored correspondence relationship between the elapsed time and the correction direction of the delivery position, and the elapsed time at a time of adjusting the delivery position.

(13) The substrate transfer method of any one of (9) to (11), wherein a rotary processing region where the rotary processor is provided and a thermal processing region where the thermal processor is provided face each other via a transfer region where the transfer arm is provided, and
wherein a guide that extends in a predetermined direction to guide movement of the transfer arm is provided in the thermal processing region.

(14) The substrate transfer method of (10) or (11), wherein a rotary processing region where the rotary processor is provided and a thermal processing region where the thermal processor is provided face each other via a transfer region where the transfer arm is provided,
wherein a guide that extends in a predetermined direction to guide movement of the transfer arm is provided in the thermal processing region, and
wherein the relating position is an exhaust duct connected to the thermal processor.

(15) The substrate transfer method of (14), wherein the exhaust duct is provided at a position in the thermal processing region, the position being among a plurality of thermal processors and on an opposite side of the guide to the rotary processor.

(16) The substrate transfer method of any one of (13) to (15), wherein a plurality of rotary processors is provided in the rotary processing region, and
wherein the adjusting the delivery position includes determining the correction direction of the delivery position individually for each of the rotary processors and adjusting the delivery position based on the determined correction direction.

(17) A non-transitory computer-readable storage medium storing a program, which is executed on a computer of a controller that controls a substrate transfer apparatus to cause the substrate transfer apparatus to execute a substrate transfer method, the substrate transfer method including:
transferring a substrate to a rotary processor by using a transfer arm of the substrate transfer apparatus, wherein the rotary processor is provided in a common housing with a thermal processor for performing thermal processing on the substrate and configured to hold and rotate the substrate for processing,
wherein the transferring the substrate includes:
   when a setting of the processing temperature in the thermal processing part is changed,
   acquiring a correction amount of a delivery position, which is a position of the transfer arm when the substrate is delivered to the rotary processor;
   determining a correction direction of the delivery position according to an elapsed time after the setting is changed; and
   adjusting the delivery position based on the acquired correction amount and the determined correction direction.

What is claimed is:

1. A substrate transfer apparatus for transferring a substrate to a rotary processor, which is provided in a common housing with a thermal processor for performing thermal processing on the substrate and configured to hold and rotate the substrate for processing, the apparatus comprising:
a transfer arm that supports and moves the substrate; and
a controller that controls an operation of the transfer arm,
wherein the controller performs:
when a setting of a processing temperature in the thermal processor is changed,
acquiring a correction amount of a delivery position, which is a position of the transfer arm when the substrate is delivered to the rotary processor;
determining a correction direction of the delivery position according to an elapsed time after the setting is changed; and
adjusting the delivery position based on the acquired correction amount and the determined correction direction.

2. The substrate transfer apparatus of claim 1, further comprising a measurer that measures a temperature at a position relating to the thermal processing in the thermal processor,
wherein the controller acquires the correction amount of the delivery position according to an amount of change in temperature at the relating position measured by the measurer during a predetermined period of time.

3. The substrate transfer apparatus of claim 2, further comprising a memory that pre-stores a correspondence relationship between the amount of change in temperature at the relating position during the predetermined period of time and the correction amount of the delivery position,
wherein the controller acquires the correction amount of the delivery position based on the amount of change in the measured temperature at the relating position during the predetermined period of time and the pre-stored correspondence relationship.

4. The substrate transfer apparatus of claim 1, further comprising a memory that pre-stores a correspondence relationship between the elapsed time and the correction direction of the delivery position,
wherein the controller determines the correction direction of the delivery position based on the elapsed time at a time of adjusting the delivery position and the pre-stored correspondence relationship.

5. A substrate processing apparatus, wherein a rotary processing region where the rotary processor is provided and a thermal processing region where the thermal processor is provided faces each other via a transfer region where the transfer arm of the substrate transfer apparatus of claim 1 is provided,
wherein the substrate transfer apparatus further comprises a guide that extends in a predetermined direction to guide movement of the transfer arm, and
wherein the guide is provided in the thermal processing region.

6. A substrate processing apparatus, wherein a rotary processing region where a rotary processor is provided and a thermal processing region where a thermal processor is provided face each other via a transfer region where the transfer arm of the substrate transfer apparatus of claim 2 is provided,
wherein the substrate transfer apparatus further comprises a guide that extends in a predetermined direction to guide movement of the transfer arm,
wherein the guide is provided in the thermal processing region, and
wherein the relating position is an exhaust duct connected to the thermal processor.

7. The substrate processing apparatus of claim 6, wherein the exhaust duct is provided at a position in the thermal processing region, the position being among a plurality of thermal processors and on an opposite side of the guide to the rotary processor.

8. The substrate processing apparatus of claim 5, wherein a plurality of rotary processors is provided in the rotary processing region, and
wherein the controller determines the correction direction of the delivery position individually for each of the rotary processors and adjusts the delivery position based on the determined correction direction.

9. A substrate transfer method comprising transferring a substrate to a rotary processor by using a transfer arm, wherein the rotary processor is provided in a common housing with a thermal processor for performing thermal processing on the substrate and configured to hold and rotate the substrate for processing,
wherein the transferring the substrate includes:
when a setting of the processing temperature in the thermal processor is changed,
acquiring a correction amount of a delivery position, which is a position of the transfer arm when the substrate is delivered to the rotary processor;
determining a correction direction of the delivery position according to an elapsed time after the setting is changed; and
adjusting the delivery position based on the acquired correction amount and the determined correction direction.

10. The substrate transfer method of claim 9, wherein the adjusting the delivery position includes acquiring the correction amount of the delivery position according to an amount of change in temperature measured by a measurer at a position relating to the thermal processing in the thermal processor during a predetermined period of time.

11. The substrate transfer method of claim 10, wherein the acquiring the correction amount includes determining the correction amount of the delivery position based on a pre-stored correspondence relationship between the amount of change in temperature at the relating position during the predetermined period of time and the correction amount for the delivery position, and the amount of change in the measured temperature at the relating position during the predetermined period of time.

12. The substrate transfer method of claim 9, wherein the adjusting the delivery position includes determining the correction direction of the delivery position based on a pre-stored correspondence relationship between the elapsed time and the correction direction of the delivery position, and the elapsed time at a time of adjusting the delivery position.

13. The substrate transfer method of claim 9, wherein a rotary processing region where the rotary processor is provided and a thermal processing region where the thermal processor is provided face each other via a transfer region where the transfer arm is provided, and
wherein a guide that extends in a predetermined direction to guide movement of the transfer arm is provided in the thermal processing region.

14. The substrate transfer method of claim 10, wherein a rotary processing region where the rotary processor is provided and a thermal processing region where the thermal processor is provided face each other via a transfer region where the transfer arm is provided,
wherein a guide that extends in a predetermined direction to guide movement of the transfer arm is provided in the thermal processing region, and
wherein the relating position is an exhaust duct connected to the thermal processor.

15. The substrate transfer method of claim 14, wherein the exhaust duct is provided at a position in the thermal processing region, the position being among a plurality of thermal processors and on an opposite side of the guide to the rotary processor.

16. The substrate transfer method of claim 13, wherein a plurality of rotary processors is provided in the rotary processing region, and
wherein the adjusting the delivery position includes determining the correction direction of the delivery position individually for each of the rotary processors and adjusting the delivery position based on the determined correction direction.

17. A non-transitory computer-readable storage medium storing a program, which is executed on a computer of a controller that controls a substrate transfer apparatus to cause the substrate transfer apparatus to execute a substrate transfer method, the substrate transfer method comprising:
transferring a substrate to a rotary processor by using a transfer arm of the substrate transfer apparatus, wherein the rotary processor is provided in a common housing with a thermal processor for performing thermal processing on the substrate and configured to hold and rotate the substrate for processing,
wherein the transferring the substrate includes:
when a setting of the processing temperature in the thermal processing part is changed,
acquiring a correction amount of a delivery position, which is a position of the transfer arm when the substrate is delivered to the rotary processor;
determining a correction direction of the delivery position according to an elapsed time after the setting is changed; and
adjusting the delivery position based on the acquired correction amount and the determined correction direction.
